(19) United States
(12) Patent Application Publication
(10) Pub. No.: US 2007/0063185 A1
(43) Pub. Date: Mar. 22, 2007

(54) Semiconductor device including a front side strained superlattice layer and a back side stress layer

(75) Inventor: Kalipatnam Vivek Rao, Grafton, MA (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: RJ Mears, LLC, Waltham, MA (US)

(21) Appl. No.: 11/534,796

(22) Filed: Sep. 25, 2006

Related U.S. Application Data
(63) Continuation-in-part of application No. 11/457,256, filed on Jul. 13, 2006.
Application No. 11/457,256 is a continuation-in-part of application No. 10/941,062, filed on Sep. 14, 2004.
Application No. 11/457,256 is a continuation-in-part of application No. 10/940,594, filed on Sep. 14, 2004.
Application No. 11/457,256 is a continuation-in-part of application No. 11/042,270, filed on Jan. 25, 2005.
Application No. 11/042,270 is a continuation-in-part of application No. 10/647,069, filed on Aug. 22, 2003, now Pat. No. 6,897,472.
Application No. 10/940,594 is a continuation-in-part of application No. 10/647,069, filed on Aug. 22, 2003, now Pat. No. 6,897,472.
Application No. 10/941,062 is a continuation-in-part of application No. 10/647,069, filed on Aug. 22, 2003, now Pat. No. 6,897,472.
Application No. 10/647,069 is a continuation of application No. 10/603,621, filed on Jun. 26, 2003, now abandoned.
Application No. 10/647,069 is a continuation of application No. 10/603,696, filed on Jun. 26, 2003, now abandoned.
(60) Provisional application No. 60/720,582, filed on Sep. 26, 2005.

(51) Int. Cl. H01L 29/06

(52) U.S. Cl. 257/18; 257/192

(57) ABSTRACT

A semiconductor device may include a semiconductor substrate having front and back surfaces, a strained superlattice layer adjacent the front surface of the semiconductor substrate and comprising a plurality of stacked groups of layers, and a stress layer on the back surface of the substrate and comprising a material different than the semiconductor substrate. Each group of layers of the strained superlattice layer may include a plurality of stacked base semiconductor monolayers defining a base semiconductor portion and at least one non-semiconductor monolayer constrained within a crystal lattice of adjacent base semiconductor portions.

### CROSS-REFERENCE TO RELATED APPLICATIONS

This application claims the benefit of U.S. Provisional Application No. 60/720,582 filed Sep. 26, 2005, and is a continuation-in-part of U.S. patent application Ser. No. 11/457,256, filed Jul. 13, 2006, which is a continuation-in-part of U.S. patent application Ser. Nos. 10/941,062 and 10/940,594 filed Sep. 14, 2004, and 11/042,270 filed on Jan. 25, 2005, which, in turn, are a continuation-in-parts of U.S. patent application Ser. No. 10/647,069 filed on Aug. 22, 2003, now U.S. Pat. No. 6,897,472, which is a continuation of U.S. patent application Ser. No. 10/603,621 filed on Jun. 26, 2003, and a continuation of U.S. patent application Ser. No. 10/603,696 filed on Jun. 26, 2003, now abandoned, the entire disclosures of which are incorporated by reference herein.

### FIELD OF THE INVENTION

The present invention relates to the field of semiconductors, and, more particularly, to semiconductors having enhanced properties based upon energy band engineering and associated methods.

### BACKGROUND OF THE INVENTION

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fraction or a binary compound semiconductor layers, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO₂/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen, The Si/O superlattice is disclosed as useful in a silicon quantum and light-emitting devices. In particular, a green electromuminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

Published International Application WO 02/103,767 A1 to Wang, Tsu and Lofgren, discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Despite considerable efforts at materials engineering to increase the mobility of charge carriers in semiconductor devices, there is still a need for greater improvements. Greater mobility may increase device speed and/or reduce device power consumption. With greater mobility, device performance can also be maintained despite the continued shift to smaller devices and new device configurations. Moreover, it may also be desirable to introduce preferential strain in band-engineered semiconductor materials to further enhance the performance characteristics thereof.

### SUMMARY OF THE INVENTION

In view of the foregoing background, it is therefore an object of the present invention to provide a semiconductor device having desired mobility and strain characteristics.

This and other objects, features, and advantages in accordance with the invention are provided by a semiconductor device which may include a semiconductor substrate having front and back surfaces, a strained superlattice layer adjacent the front surface of the semiconductor substrate and comprising a plurality of stacked groups of layers, and a stress layer on the back surface of the substrate and comprising a material different than the semiconductor substrate. More particularly, each group of layers of the strained superlattice layer may include a plurality of stacked base semiconductor monolayers defining a base semiconductor portion, and at least one non-semiconductor monolayer constrained within a crystal lattice of adjacent base semiconductor portions.

By way of example, the stress layer may be an oxide, a nitride, another superlattice, etc. The semiconductor device may further include regions for causing transport of charge carriers through the strained superlattice layer in a parallel direction relative to the stacked groups of layers. The strained superlattice layer may have a compressive strain as well as a tensile strain.

In addition, each base semiconductor portion may include silicon, and each non-semiconductor monolayer may include oxygen. More generally, each base semiconductor portion may include a base semiconductor selected from the group consisting of Group IV semiconductors, Group III-V semiconductors, and Group II-VI semiconductors, and each non-semiconductor monolayer may include a non-semiconductor selected from the group consisting of oxygen, nitrogen, fluorine, and carbon-oxygen. Furthermore, adjacent base semiconductor portions of the superlattice may be chemically bound together. Also, each non-semiconductor monolayer may be a single monolayer thick. Additionally, the strained superlattice layer may further include a base semiconductor cap layer on an uppermost group of layers.

The semiconductor substrate may comprise a monocrystalline silicon substrate, for example. Also by way of example, the semiconductor substrate may have a thickness of less than about 700 microns.

### BRIEF DESCRIPTION OF THE DRAWINGS

FIG. 1 is a schematic cross-sectional view of a semiconductor device in accordance with the present invention including a strained superlattice and a stress layer.

FIG. 2 is a greatly enlarged schematic cross-sectional view of the superlattice as shown in FIG. 1.

FIG. 3 is a perspective schematic atomic diagram of a portion of the superlattice shown in FIG. 1.

FIG. 4 is a greatly enlarged schematic cross-sectional view of another embodiment of a superlattice that may be used in the device of FIG. 1.

FIG. 5A is a graph of the calculated band structure from the gamma point (G) for both bulk silicon as in the prior art, and for the 4/1 Si/O superlattice as shown in FIGS. 1-3.

FIG. 5B is a graph of the calculated band structure from the Z point for both bulk silicon as in the prior art, and for the 4/1 Si/O superlattice as shown in FIGS. 1-3.

FIG. 5C is a graph of the calculated band structure from both the gamma and Z points for both bulk silicon as in the prior art, and for the 5/1/3/1 Si/O superlattice as shown in FIG. 4.

FIGS. 6 and 7 are schematic cross-sectional views illustrating steps for forming the stress layer and strained superlattice of the device of FIG. 1.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similar elements in alternative embodiments.

The present invention relates to controlling the properties of semiconductor materials at the atomic or molecular level to achieve improved performance within semiconductor devices. Further, the invention relates to the identification, creation, and use of improved materials for use in the conduction paths of semiconductor devices.

Applicants theorize, without wishing to be bound thereto, that certain superlattices as described herein reduce the effective mass of charge carriers and that this thereby leads to higher charge carrier mobility. Effective mass is described with various definitions in the literature. As a measure of the improvement in effective mass Applicants use a “conductivity reciprocal effective mass tensor”, Mₑ⁻¹ and Mₕ⁻¹ for electrons and holes respectively, defined as:

$${M}_{e , ij}^{- 1} ( {E}_{F} , T ) = \frac{{\sum }_{E > {E}_{F}} {\int }_{B . Z .} {( {▽}_{k} E ( k , n ) )}_{i} {( {▽}_{k} E ( k , n ) )}_{j} \frac{\partial f ( E ( k , n ) , {E}_{F} , T )}{\partial E} {ⅆ}^{3} k}{{\sum }_{E > {E}_{F}} {\int }_{B . Z .} f ( E ( k , n ) , {E}_{F} , T ) {ⅆ}^{3} k}$$

for electrons and:

$${M}_{h , ij}^{- 1} ( {E}_{F} , T ) = \frac{- {\sum }_{E < {E}_{F}} {\int }_{B . Z .} {( {▽}_{k} E ( k , n ) )}_{i} {( {▽}_{k} E ( k , n ) )}_{j} \frac{\partial f ( E ( k , n ) , {E}_{F} , T )}{\partial E} {ⅆ}^{3} k}{{\sum }_{E < {E}_{F}} {\int }_{B . Z .} ( 1 - f ( E ( k , n ) , {E}_{F} , T ) ) {ⅆ}^{3} k}$$

for holes, where f is the Fermi-Dirac distribution, E_{F} is the Fermi energy, T is the temperature, E(k,n) is the energy of an electron in the state corresponding to wave vector k and the n^{th} energy band, the indices i and j refer to Cartesian coordinates x, y and z, the integrals are taken over the Brillouin zone (B.Z.), and the summations are taken over bands with energies above and below the Fermi energy for electrons and holes respectively.

Applicants' definition of the conductivity reciprocal effective mass tensor is such that a tensorial component of the conductivity of the material is greater for greater values of the corresponding component of the conductivity reciprocal effective mass tensor. Again Applicants theorize without wishing to be bound thereto that the superlattices described herein set the values of the conductivity reciprocal effective mass tensor so as to enhance the conductive properties of the material, such as typically for a preferred direction of charge carrier transport. The inverse of the appropriate tensor element is referred to as the conductivity effective mass. In other words, to characterize semiconductor material structures, the conductivity effective mass for electrons/holes as described above and calculated in the direction of intended carrier transport is used to distinguish improved materials.

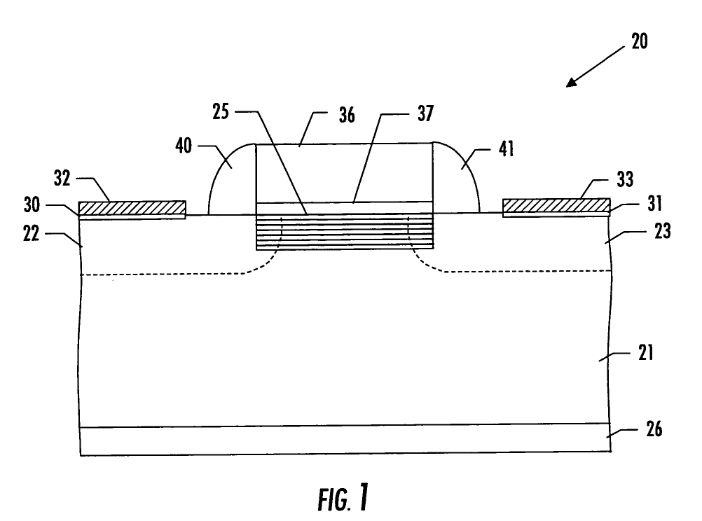

Using the above-described measures, one can select materials having improved band structures for specific purposes. One such example would be a strained superlattice 25 material for a channel region in a MOSFET device. A planar MOSFET 20 including the strained superlattice 25 in accordance with the invention is now first described with reference to FIG. 1. One skilled in the art, however, will appreciate that the materials identified herein could be used in many different types of semiconductor devices, such as discrete devices and/or integrated circuits. By way of example, another application in which the strained superlattice 25 may be used is in FINFETs, as further described in U.S. application Ser. No. 11/426,969, which is assigned to the present Assignee and is hereby incorporated herein in its entirety by reference.

The illustrated MOSFET 20 includes a semiconductor substrate 21, a stress layer 26 on a back surface of the substrate (i.e., below the substrate in FIG. 1), source and drain regions 22, 23, and the strained superlattice layer 25 on a front surface of the substrate (i.e., above, the substrate in FIG. 1) between the source and drain regions. More particularly, the substrate 21 may be implanted with an appropriate dopant(s) to provide the source and drain regions 22, 23, as will be appreciated by those skilled in the art. It should be noted that while the superlattice 25 is in contact with the front surface of the semiconductor substrate in the illustrated example, this need not be the case in all embodiments. For example, in a semiconductor-on-insulator (SOI) devices, an insulating layer may be positioned between the semiconductor substrate 21 and the superlattice 25, as will be appreciated by those skilled in the art.

The stress layer 26 may include a different material than the substrate 21 to thereby impart preferential strain on the substrate which, in turn, imparts the desired strain on the superlattice 25, as will be appreciated by those skilled in the art. By way of example, the substrate 21 may be a monocrystalline silicon substrate, and the stress layer 26 may be an oxide (e.g., silicon oxide), a nitride (e.g., silicon nitride), another semiconductor, or it may be another superlattice. Thus, it will be understood that when reference is made herein to the stress layer 26 including a different material than the substrate 21, it is meant that that (a) the stress layer may include at least one material not significantly present in the substrate (oxygen, nitrogen, etc.), although the substrate and stress layer could both include common materials such as silicon, etc., or (b) that the substrate and stress layers may be different materials (e.g., a silicon substrate and a germanium stress layer).

In particular, depending upon the particular composition of the substrate 21 and stress layer 26, either a tensile or a compressive strain may be induced in the superlattice 25, as will be appreciated by those skilled in the art. In the case of a tensile strain, this may advantageously be used to provide further mobility enhancement in N-channel FETs, for example.

Alternatively, the compositions of the substrate 21 and stress layer 26 may be chosen to induce a compressive strain in the superlattice layer 25 that may advantageously provide further mobility enhancement of the superlattice in P-channel FET devices, for example.

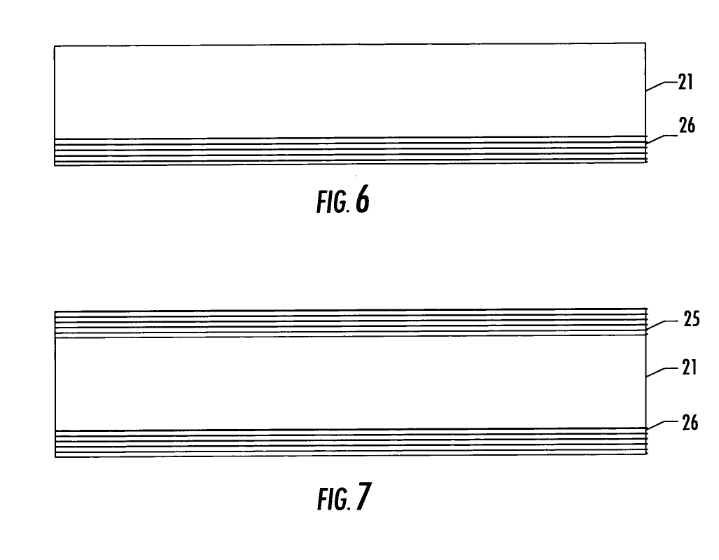

Formation of the stress layer 26 and strained superlattice 25 will now be described with reference to FIGS. 6 and 7. A low pressure chemical vapor deposition (LPCVD) or plasma enhanced CVD (PECVD) film or layer 30, which in the illustrated embodiment is a superlattice film, is deposited under appropriate conditions (temperature, pressure, thickness) for the given materials on the back surface of the substrate 21 (e.g., a single crystal (monocrystalline) silicon wafer) to advantageously cause desired strain in the wafer during manufacture of the semiconductor device 20 (FIG. 6). By way of example, the wafer or substrate 21 may have a thickness of less than about 700 microns. The strain imparted by the stress layer 26 may either be compressive or tensile, depending upon the given materials and deposition conditions, as noted above. Again, inducing desired strain in this manner allows the silicon lattice on the front (i.e., the top side opposite the film 30) surface of the wafer 21 to either expand or contract appropriately.

By controlling the deposition conditions during stress layer 26 deposition, this lattice parameter change may potentially be adjusted by the desired amount to allow a semiconductor superlattice 25, such as those described below, to be epitaxially grown on the front surface of the substrate 21 with improved lattice parameter match between the superlattice and the underlying silicon surface (FIG. 7). Applicant theorizes without wishing to be bound thereto that the use of the stress layer 30 may advantageously increase the critical thickness of the epitaxial growth due to the pre-engineered lattice parameter of the underlying silicon surface. As such, this may also allow for thicker superlattices 25 that have reduced incidence of crystalline defects as well as atomically smoother surfaces, compared to superlattices grown directly on bulk silicon wafers.

Source/drain silicide layers 30, 31 and source/drain contacts 32, 33 illustratively overlie the source/drain regions 22, 23, as will be appreciated by those skilled in the art. A gate 35 illustratively includes a gate insulating layer 37 adjacent the channel provided by the strained superlattice layer 25, and a gate electrode layer 36 on the gate layer. Sidewall spacers 40, 41 are also provided in the illustrated MOSFET 20.

It is also theorized that the semiconductor device, such as the illustrated MOSFET 20, enjoys a higher charge carrier mobility based upon the lower conductivity effective mass than would otherwise be present. In some embodiments, and as a result of the band engineering, the superlattice 25 may further have a substantially direct energy bandgap that may be particularly advantageous for opto-electronic devices, for example, such as those set forth in the co-pending application entitled INTEGRATED CIRCUIT COMPRISING AN ACTIVE OPTICAL DEVICE HAVING AN ENERGY BAND ENGINEERED SUPERLATTICE, U.S. patent application Ser. No. 10/936,903, which is assigned to the present Assignee and is hereby incorporated herein in its entirety by reference.

As will be appreciated by those skilled in the art, the source/drain regions 22, 23 and gate 35 of the MOSFET 20 may be considered as regions for causing the transport of charge carriers through the strained superlattice layer 25 in a parallel direction relative to the layers of the stacked groups 45a-45n, as will he discussed further below. That is, the channel of the device is defined within the superlattice 25. Other such regions are also contemplated by the present invention.

In certain embodiments, the superlattice 25 may advantageously act as an interface for the gate dielectric layer 37. For example, the channel region may be defined in the lower portion of the strained superlattice 25 (although some of the channel may also he defined in the semiconductor material below the superlattice), while the upper portion thereof insulates the channel from the dielectric layer 37. In still another embodiment, the channel may be defined solely in the substrate 21, and the strained superlattice layer 25 may be included merely as an insulation/interface layer, for example.

Use of the superlattice 25 as a dielectric interface layer may be particularly appropriate where relatively high-K gate dielectric materials are used. The superlattice 25 may advantageously provide reduced scattering and, thus, enhanced mobility with respect to prior art insulation layers (e.g., silicon oxides) typically used for high-K dielectric interfaces. Moreover, use of the superlattice 25 as an insulator for applications with high-K dielectrics may result in smaller overall thicknesses, and thus improved device capacitance. This is because the superlattice 25 may be formed in relatively small thicknesses yet still provide desired insulating properties, as discussed further in co-pending U.S. application Ser. No. 11/136,881, which is assigned to the present Assignee and is hereby incorporated herein in its entirety by reference.

Applicants have identified improved materials or structures for the channel region of the MOSFET 20. More specifically, the Applicants have identified materials or structures having energy band structures for which the appropriate conductivity effective masses for electrons and/or holes are substantially less than the corresponding values for silicon.

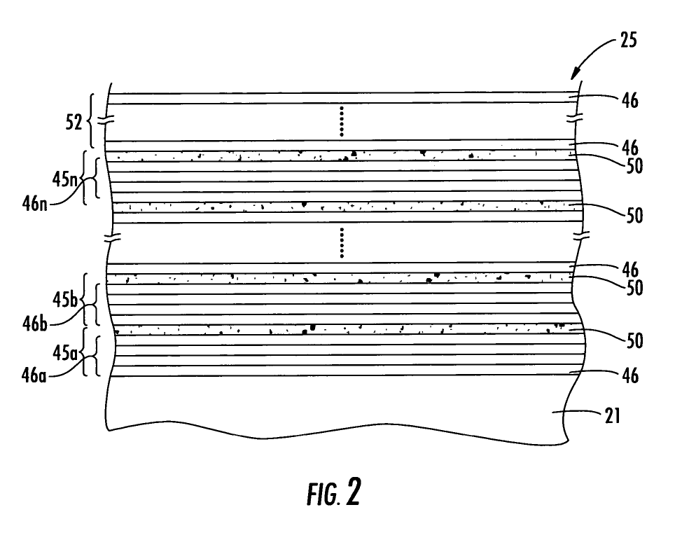

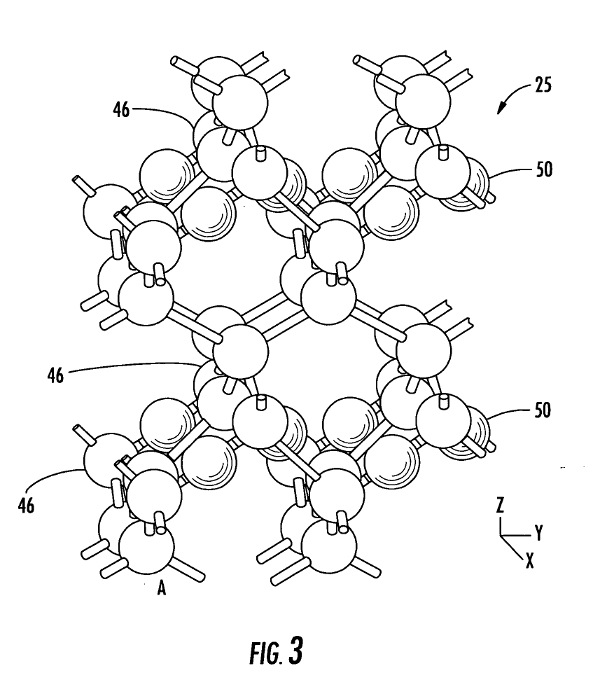

Referring now additionally to FIGS. 2 and 3, the materials or structures are in the form of a superlattice 25 whose structure is controlled at the atomic or molecular level and may be formed using known techniques of atomic or molecular layer deposition The superlattice 25 includes a plurality of layer groups 45a-45n arranged in stacked relation, as perhaps best understood with specific reference to the schematic cross-sectional view of FIG. 2. Moreover, an intermediate annealing process as described in co-pending U.S. application Ser. No. 11/136,834, which is assigned to the present Assignee and is hereby incorporated herein in its entirety by reference, may also be used to advantageously reduce defects and provide smother layer surfaces during fabrication.

Each group of layers 45a-45n of the superlattice 25 illustratively includes a plurality of stacked base semiconductor monolayers 46 defining a respective base semiconductor portion 46a-46n and an energy band-modifying layer 50 thereon. The energy band-modifying layers 50 are indicated by stippling in FIG. 2 for clarity of explanation.

The energy-band modifying layer 50 illustratively comprises one non-semiconductor monolayer constrained within a crystal lattice of adjacent base semiconductor portions. That is, opposing base semiconductor monolayers 46 in adjacent groups of layers 45a-45n are chemically bound together. For example, in the case of silicon monolayers 46, some of the silicon atoms in the upper or top semiconductor monolayer of the group of monolayers 46a will be covalently bonded with silicon atoms in the lower or bottom monolayer of the group 46b, as seen in FIG. 3. This allows the crystal lattice to continue through the groups of layers despite the presence of the non-semiconductor monolayer(s) (e.g., oxygen monolayer(s)). Of course, there will not be a complete or pure covalent bond between the opposing silicon layers 46 of adjacent groups 45a-45n as some of the silicon atoms in each of these layers will be bonded to non-semiconductor atoms (i.e., oxygen in the present example), as will be appreciated by those skilled in the art.

In other embodiments, more than one such monolayer may be possible. It should be noted that reference herein to a non-semiconductor or semiconductor monolayer means that the material used for the monolayer would be a non-semiconductor or semiconductor if formed in bulk. That is, a single monolayer of a material, such as semiconductor, may not necessarily exhibit the same properties that it would if formed in bulk or in a relatively thick layer, as will be appreciated by those skilled in the art.

Applicants theorize without wishing to be bound thereto that energy band-modifying layers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure.

It is also theorized that the semiconductor device, such as the illustrated MOSFET 20, enjoys a higher charge carrier mobility based upon the lower conductivity effective mass than would otherwise be present. In some embodiments, and as a result of the band engineering achieved by the present invention, the superlattice 25 may further have a substantially direct energy bandgap that may be particularly advantageous for opto-electronic devices, for example, as described in further detail below. Of course, all of the above-described properties of the superlattice 25 need not be utilized in every application. For example, in some applications the superlattice 25 may only be used for its dopant blocking/insulation properties or its enhanced mobility, or it may be used for both in other applications, as will be appreciated by those skilled in the art.

In some embodiments, more than one non-semiconductor monolayer may be present in the energy band modifying layer 50. By way of example, the number of non-semiconductor monolayers in the energy band-modifying layer 50 may preferably be less than about five monolayers to thereby provide the desired energy band-modifying properties.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors as will be appreciated by those skilled in the art. More particularly, the base semiconductor may comprise at least one of silicon and germanium, for example.

Each energy band-modifying layer 50 may comprise a non-semiconductor selected from the group consisting of oxygen, nitrogen, fluorine, and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art.

It should be noted that the term monolayer is meant to include a single atomic layer and also a single molecular layer. It is also noted that the energy band-modifying layer 50 provided by a single monolayer is also meant to include a monolayer wherein not all of the possible sites are occupied, as noted above. For example, with particular reference to the atomic diagram of FIG. 3, a 4/1 repeating structure is illustrated for silicon as the base semiconductor material, and oxygen as the energy band-modifying material. Only half of the possible sites for oxygen are occupied.

In other embodiments and/or with different materials this one half occupation would not necessarily be the case, as will be appreciated by those skilled in the art. Indeed it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein Atomic or monolayer deposition is also now widely used. Accordingly, semiconductor devices incorporating the superlattice 25 may be readily adopted and implemented as will be appreciated by those skilled in the art.

It is theorized without Applicants wishing to be bound thereto that for a superlattice, such as the Si/O superlattice, for example, that the number of silicon monolayers should desirably be seven or less so that the energy band of the superlattice is common or relatively uniform throughout to achieve the desired advantages. Of course, more than seven silicon layers may be used in some embodiments. The 4/1 repeating structure shown in FIGS. 2 and 3, for Si/O has been modeled to indicate an enhanced mobility for electrons and holes in the X direction. For example, the calculated conductivity effective mass for electrons (isotropic for bulk silicon) is 0.26 and for the 4/1 SiO superlattice in the X direction it is 0.12 resulting in a ratio of 0.46. Similarly, the calculation for holes yields values of 0.36 for bulk silicon and 0.16 for the 4/1 Si/O superlattice resulting in a ratio of 0.44.

While such a directionally preferential feature may be desired in certain semiconductor devices, other devices may benefit from a more uniform increase in mobility in any direction parallel to the groups of layers. It may also be beneficial to have an increased mobility for both electrons or holes, or just one of these types of charge carriers as will be appreciated by those skilled in the art.

The lower conductivity effective mass for the 4/1 Si/O embodiment of the superlattice 25 may be less than two-thirds the conductivity effective mass than would otherwise occur, and this applies for both electrons and holes. Of course, the superlattice 25 may further comprise at least one type of conductivity dopant therein as will also be appreciated by those skilled in the art It may be especially appropriate to dope at least a portion of the superlattice 25 if the superlattice is to provide some or all of the channel. However, the superlattice 25 or portions thereof may also remain substantially undoped in some embodiments, as described further in U.S. application Ser. No. 11/136,757, which is assigned to the present Assignee and is hereby incorporated herein in its entirety by reference.

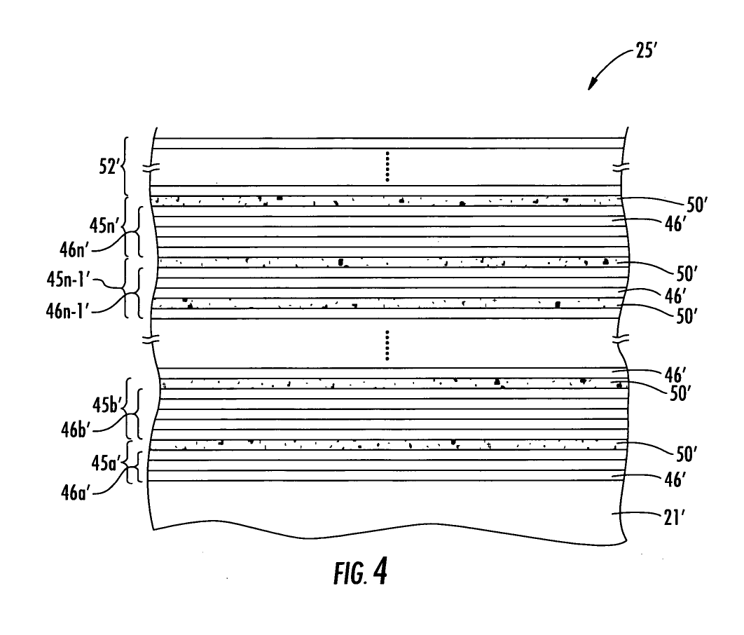

Referring now additionally to FIG. 4, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The energy band-modifying layers 50′ may each include a single monolayer. For such a superlattice 25′ including Si/O, the enhancement of charge carrier mobility is independent of orientation in the plane of the layers Those other elements of FIG. 4 not specifically mentioned are similar to those discussed above with reference to FIG. 2 and need no further discussion herein.

In some device embodiments, all of the base semiconductor portions of a superlattice may be a same number of monolayers thick. In other embodiments, at least some of the base semiconductor portions may he a different number of monolayers thick. In still other embodiments, all of the base semiconductor portions may be a different number of monolayers thick.

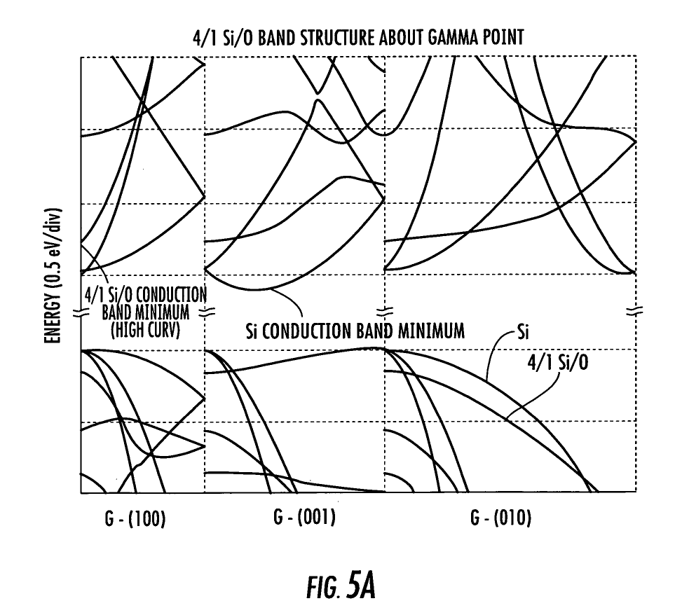

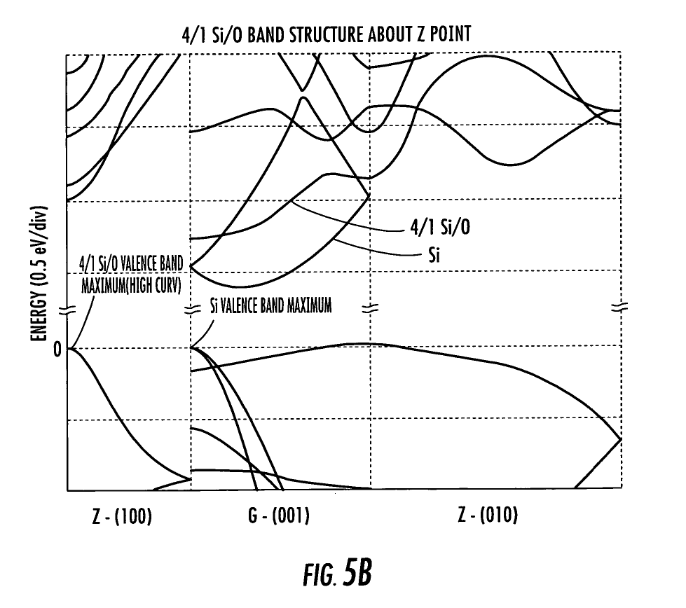

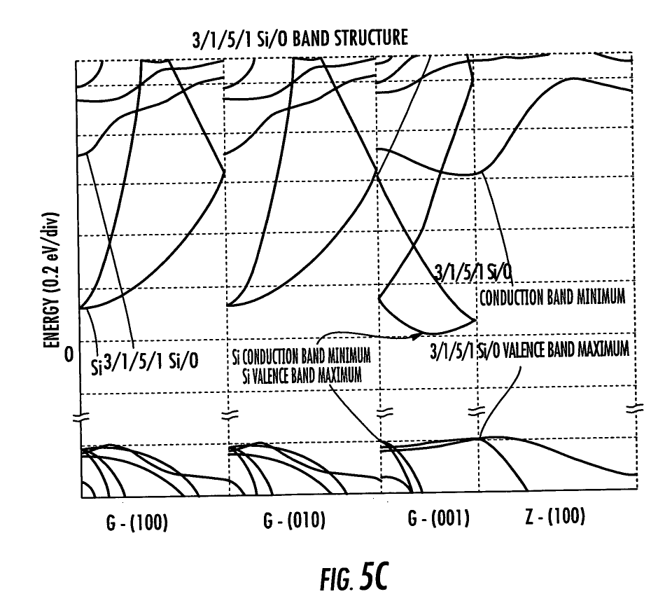

In FIGS. 5A-5C band structures calculated using Density Functional Theory (DFT) are presented. It is well known in the art that DFT underestimates the absolute value of the bandgap. Hence all bands above the gap may be shifted by an appropriate “scissors correction.” However, the shape of the band is known to be much more reliable. The vertical energy axes should be interpreted in this light.

FIG. 5A shows the calculated band structure from the gamma point (G) for both bulk silicon (represented by continuous lines) and for the 4/1 Si/O superlattice 25 as shown in FIGS. 1-3 (represented by dotted lines). The directions refer to the unit cell of the 4/1 Si/O structure and not to the conventional unit cell of Si, although the (001) direction in the figure does correspond to the (001) direction of the conventional unit cell of Si, and, hence, shows the expected location of the Si conduction band minimum. The (100) and (010) directions in the figure correspond to the (110) and (−110) directions of the conventional Si unit cell. Those skilled in the art will appreciate that the bands of Si on the figure are folded to represent them on the appropriate reciprocal lattice directions for the 4/1 Si/O structure.

It can be seen that the conduction band minimum for the 4/1 Si/O structure is located at the gamma point in contrast to bulk silicon (Si), whereas the valence band minimum occurs at the edge of the Brillouin zone in the (001) direction which we refer to as the Z point. One may also note the greater curvature of the conduction band minimum for the 4/1 Si/O structure compared to the curvature of the conduction band minimum for Si owing to the band splitting due to the perturbation introduced by the additional oxygen layer.

FIG. 5B shows the calculated band structure from the Z point for both bulk silicon (continuous lines) and for the 4/1 Si/O superlattice 25 (dotted lines). This figure illustrates the enhanced curvature of the valence band in the (100) direction.

FIG. 5C shows the calculated band structure from the both the gamma and Z point for both bulk silicon (continuous lines) and for the 5/1/3/1 Si/O structure of the superlattice 25′ of FIG. 4 (dotted lines). Due to the symmetry of the 5/1/3/1 Si/O structure, the calculated band structures in the (100) and (010) directions are equivalent. Thus the conductivity effective mass and mobility are expected to be isotropic in the plane parallel to the layers, i.e. perpendicular to the (001) stacking direction. Note that in the 5/1/3/1 Si/O example the conduction band minimum and the valence band maximum are both at or close to the Z point.

Although increased curvature is an indication of reduced effective mass, the appropriate comparison and discrimination may be made via the conductivity reciprocal effective mass tensor calculation. This leads Applicants to further theorize that the 5/1/3/1 superlattice 25′ should be substantially direct bandgap. As will be understood by those skilled in the art, the appropriate matrix element for optical transition is another indicator of the distinction between direct and indirect bandgap behavior.

Further details regarding the use of stress layers for imparting preferential strain in a superlattice and exemplary configurations are provided in the above-noted co-pending U.S. patent application Ser. No. 11/457,256.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended.

That which is claimed is:

1. A semiconductor device comprising:
a semiconductor substrate having front and back surfaces;
a strained superlattice layer adjacent the front surface of said semiconductor substrate and comprising a plurality of stacked groups of layers; and
a stress layer on the back surface of said semiconductor substrate and comprising a material different than said semiconductor substrate;
each group of layers of said strained superlattice layer comprising a plurality of stacked base semiconductor monolayers defining a base semiconductor portion and at least one non-semiconductor monolayer constrained within a crystal lattice of adjacent base semiconductor portions.

2. The semiconductor device of claim 1 wherein said stress layer comprises an oxide.

3. The semiconductor device of claim 1 wherein said stress layer comprises a nitride.

4. The semiconductor device of claim 1 wherein said stress layer also comprises a superlattice.

5. The semiconductor device of claim 1 further comprising regions for causing transport of charge carriers through said strained superlattice layer in a parallel direction relative to the stacked groups of layers.

6. The semiconductor device of claim 1 wherein said strained superlattice layer has a compressive strain.

7. The semiconductor device of claim 1 wherein said strained superlattice layer has a tensile strain.

8. The semiconductor device of claim 1 wherein each base semiconductor portion comprises silicon.

9. The semiconductor device of claim 1 wherein each base semiconductor portion comprises a base semiconductor selected from the group consisting of Group IV semiconductors, Group III-V semiconductors, and Group II-VI semiconductors.

10. The semiconductor device of claim 1 wherein each non-semiconductor monolayer comprises oxygen.

11. The semiconductor device of claim 1 wherein each non-semiconductor monolayer comprises a non-semiconductor selected from the group consisting of oxygen, nitrogen, fluorine, and carbon-oxygen.

12. The semiconductor device of claim 1 wherein adjacent base semiconductor portions are chemically bound together.

13. The semiconductor device of claim 1 wherein each non-semiconductor monolayer is a single monolayer thick.

14. The semiconductor device of claim 1 wherein said strained superlattice layer further comprises a base semiconductor cap layer on an uppermost group of layers.

15. The semiconductor device of claim 1 further comprising an insulating layer between said semiconductor substrate and said superlattice.

16. The semiconductor device of claim 1 wherein said semiconductor substrate comprises a monocrystalline silicon substrate.

17. The semiconductor substrate of claim 1 wherein said semiconductor substrate has a thickness of less than about 700 microns.

18. A semiconductor device comprising:
a semiconductor substrate having front and back surfaces;
a strained superlattice layer adjacent the front surface of said semiconductor substrate and comprising a plurality of stacked groups of layers; and
a stress layer on the back surface of said semiconductor substrate and comprising a material different than said semiconductor substrate;
each group of layers of said strained superlattice layer comprising a plurality of stacked base silicon monolayers defining a base silicon portion and at least one oxygen monolayer constrained within a crystal lattice of adjacent base silicon portions.

19. The semiconductor device of claim 19 wherein said stress layer comprises at least one of an oxide and a nitride.

20. The semiconductor device of claim 19 wherein said stress layer also comprises a superlattice.

21. The semiconductor device of claim 19 further comprising regions for causing transport of charge carriers through said strained superlattice layer in a parallel direction relative to the stacked groups of layers.

22. The semiconductor device of claim 19 wherein said strained superlattice layer has a compressive strain.

23. The semiconductor device of claim 19 wherein said strained superlattice layer has a tensile strain.

24. The semiconductor device of claim 19 wherein adjacent base semiconductor portions are chemically bound together.

25. The semiconductor device of claim 19 wherein said semiconductor substrate comprises a monocrystalline silicon substrate.
